(19) United States
(12) Patent Application Publication
(10) Pub. No.: US 2013/0111810 A1
(43) Pub. Date: May 9, 2013

(54) PHOTOVOLTAIC MODULES FOR AN AGRICULTURAL GREENHOUSE AND METHOD FOR MANUFACTURING SUCH MODULES

(71) Applicants: Philippe Edouard Gravisse, Paris (FR); François Le Poull, Lannion (FR)

(72) Inventors: Philippe Edouard Gravisse, Paris (FR); François Le Poull, Lannion (FR)

(73) Assignees: CASCADE, Rueil Malmaison (FR); LABORATOIRE DE PHYSIQUE DU RAYONNEMENT ET DE LA LUMIÈRE, Paris (FR)

(21) Appl. No.: 13/579,424

(22) PCT Filed: Feb. 11, 2011
(86) PCT No.: PCT/EP2011/052012

§ 371 Date: Jan. 25, 2013

(30) Foreign Application Priority Data
Feb. 19, 2010 (FR) 10/00696

(51) Int. Cl. H01L 31/055; H01L 31/18; A01G 9/14

(52) U.S. Cl. CPC H01L 31/055; A01G 9/14; H01L 31/18
USPC 47/17; 136/247; 438/73

(57) ABSTRACT

A photovoltaic module for an agricultural greenhouse includes a front plate, intended to be in contact with the sunlight, a back substrate and an assembly of photovoltaic cells arranged between the front plate and the back substrate. The photovoltaic module has a cell packing factor of substantially between 0.2 and 0.8, and includes at least one layer of a light-cascade doped material enhancing photosynthesis for absorbing the sunlight in at least one range of wavelengths for retransmitting same in at least a second range of wavelengths, enhancing the photosynthesis of at least one plant species.

### CROSS-REFERENCE TO RELATED APPLICATIONS

This application is a National Phase Entry of International Application No. PCT/EP2011/052012, filed on Feb. 11, 2011, which claims priority to French Patent Application Serial No. 10/00696, filed on Feb. 19, 2010, both of which are incorporated by reference herein.

### FIELD OF THE INVENTION

The invention relates to photovoltaic modules for agricultural greenhouses for assisting the cultivation of plant species.

### BACKGROUND

In the techniques for producing conventional photovoltaic modules, arranging photovoltaic cells, generally opaque and treated so as to be non-reflective, in materials with high transmittance in the solar spectrum on the front face and highly reflective on the rear face in order serve as a protective screen is known. At the initiative of some manufacturers, the use of photovoltaic generators is becoming widespread and applications thereof concern more and more the agricultural field, where they are placed on the roofs of rural buildings or on agricultural greenhouses.

The photovoltaic modules used, placed on agricultural greenhouses, come into competition with the plant species for the use of the sunlight available, which then as a priority benefits the photovoltaic function of the photovoltaic modules to the detriment of the photosynthesis and growth of the plant species. The compromise generally used by greenhouse gardeners or agronomists is then to close off the north side of agricultural greenhouses in order to place the photovoltaic modules thereon while allowing the solar energy to enter the greenhouse through the other sides to permit the growth of the plant species. This compromise is detrimental to the photovoltaic function, which then receives only indirect light on the north face, just as plants in the greenhouses are deprived of the diffuse energy of the albedo issuing from the north celestial canopy, the contribution of which to the growth of the plant species is not insignificant.

The present invention relates in particular to a photovoltaic module for agricultural greenhouses for assisting the cultivation of plant species.

### SUMMARY

According to a first aspect of the present invention, a photovoltaic module for agricultural greenhouses comprises a front plate intended to be in contact with the sunlight, a rear substrate and a set of photovoltaic cells arranged between the front plate and the rear substrate. The photovoltaic module has a cell packing factor of between approximately 0.2 and 0.8, and comprises at least one layer of a light-cascade doped material enhancing photosynthesis, capable of absorbing sunlight in at least one range of wavelengths in order to re-emit it in at least a second range of wavelengths favourable to the photosynthesis of at least one plant species.

According to a variant of the first subject matter of the present invention, at least one of the front plate and rear substrate forms or is coated with the layer of light-cascade doped material enhancing photosynthesis. According to another variant of the first subject matter of the present invention, all the photovoltaic cells are arranged in an organic matrix or between two organic films. According to another variant of the first subject matter of the present invention, at least one of the organic matrix and the two organic films forms a layer of light-cascade doped material enhancing photosynthesis.

According to another variant of the first subject of the present invention, the light-cascade doped material enhancing photosynthesis absorbs the sunlight in the range of wavelengths 300 to 400 nm in order to re-emit it in the range of wavelengths 410 to 500 nm. According to another variant of the first subject matter of the present invention, the light-cascade doped material enhancing photosynthesis absorbs the sunlight in the range of wavelengths 510 to 590 nm in order to re-emit it in the range of wavelengths 600 to 750 nm. According to another variant of the first subject matter of the present invention the front plate and the rear substrate of the photovoltaic module comprise glass, and at least one of the front plate and the rear substrate is coated with a layer of light-cascade doped material enhancing photosynthesis.

According to another variant of the first subject matter of the present invention, the front plate and the rear substrate of the photovoltaic module comprise polymethyl methacrylate, and at least one of the front plate and the rear substrate forms the layer of light-cascade doped material enhancing photosynthesis. According to another variant of the first subject matter of the present invention, the rear substrate forms or is coated with the layer of light-cascade doped material enhancing photosynthesis, and the front plate of the photovoltaic forms or is coated with a layer of a light-cascade doped material enhancing the photovoltaic function able to absorb sunlight in at least one range of wavelengths in order to re-emit it in at least a second range of wavelengths of greater sensitivity of the photovoltaic cells. According to yet another variant of the first subject matter of the present invention, the layer of light-cascade doped material enhancing the photovoltaic function or enhancing photosynthesis comprises a matrix comprising at least one compound chosen from the group comprising silicones, polycarbonates, ethylene vinyl acetate, polyethylene, polymethyl methacrylate, polyvinyl butyral, glasses and derivatives thereof. According to a variant of the first subject matter of the present invention, the light-cascade doped material enhancing the photovoltaic function or photosynthesis comprises at least one compound chosen from the group comprising lanthanides, the uranyl ion, aromatic cyclic compounds of the N-ring type, N being an integer chosen from 3, 4, 5 or more, and derivatives thereof.

According to a second aspect of the present invention, an agricultural greenhouse is covered on at least part of its surface with at least one photovoltaic module according to the first subject matter of the present invention. According to a third aspect of the invention, a method of manufacturing photovoltaic modules of the type comprises a front plate intended to be in contact with sunlight, a rear substrate and a set of voltaic cells arranged between the front plate and the rear substrate. The method comprises at least the steps of distributing the photovoltaic cells on the rear substrate so that the photovoltaic module obtained has a cell packing factor lying approximately between 0.2 and 0.8, and of incorporating or coating on at least one of the front plate and the rear substrate a light-cascade doped material enhancing photosynthesis capable of absorbing sunlight in at least one range of wavelengths in order to re-emit it at least a second range of wavelengths favourable to photosynthesis of at least one plant species.

### BRIEF DESCRIPTION OF THE DRAWINGS

Other advantages and features of the invention will emerge from a reading of the following description, illustrated by the following figures:

FIG. 1 shows a plan view of a photovoltaic module according to one embodiment of the present invention.

FIG. 2 is a graph showing the spectral response of the two types of chlorophyll present in plant species.

FIG. 3 is a diagram showing the operating principle of a light cascade.

FIG. 4 is a graph showing the solar spectrum and the solar spectrum modified by a photovoltaic module comprising a light-cascade doped material enhancing photosynthesis according to one embodiment of the present invention.

FIG. 5 is a graph showing the solar spectrum and the solar spectrum modified by a photovoltaic module comprising a light-cascade doped material enhancing the photovoltaic function according to one embodiment of the present invention.

FIGS. 6a to 6d are transverse sections of photovoltaic modules according to embodiments of the present invention.

FIG. 7 shows an example of an agricultural greenhouse covered with several photovoltaic modules according to one embodiment of the present invention.

### DETAILED DESCRIPTION

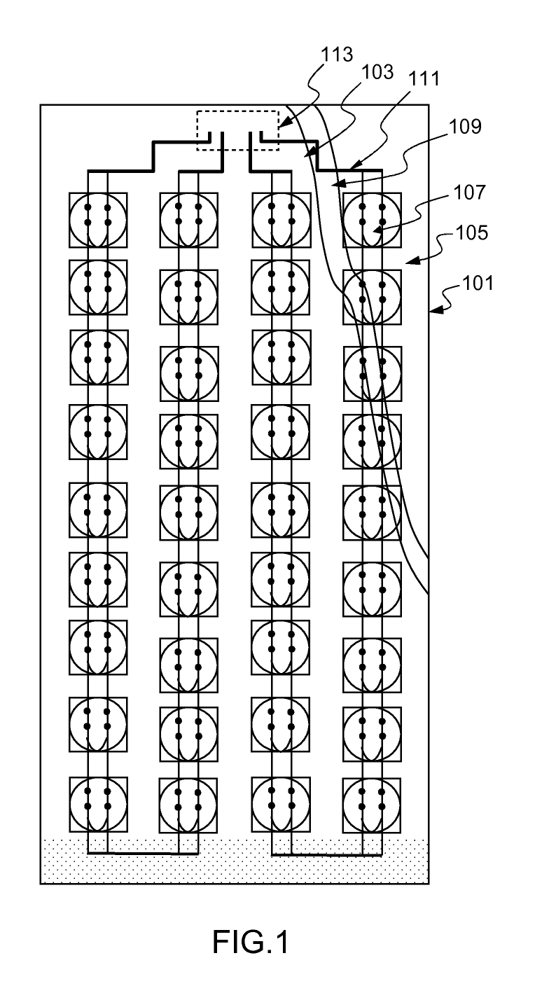

FIG. 1 shows a photovoltaic module according to one embodiment of the invention. The photovoltaic module 101 comprises a front or external plate 103 intended to receive the sunlight, a rear or internal substrate 105, as well as a set of photovoltaic cells 107 arranged between the front plate 103 and the rear substrate 105 of the photovoltaic module. According to one embodiment of the present invention, the front plate 103 and the rear substrate 105 of the photovoltaic module 101 each comprise at least one compound chosen from the group comprising silicones, fluorinated polymers, polycarbonates, ethylene vinyl acetate (EVA), polyethylene (PE), polymethyl methacrylate (PMMA), polyvinyl butyral (PVB), glasses, such as phosphate, silicate or borosilicate glasses, and derivatives thereof. According to one embodiment of the present invention, the front plate 103 and the rear substrate 105 have a mean thickness of between 0.5 and 5 mm.

According to one embodiment of the present invention, the photovoltaic cells 107 are large-surface junction diodes, of the unijunction or multijunction type. The photovoltaic cells 107 are of the silicon type, such as amorphous, monocrystalline or multicrystalline silicon, or of the CdTe or CISG (Copper-Indium-Selenium-Gallium) type.

All the photovoltaic cells 107 of the photovoltaic module 101 according to one embodiment of the invention are arranged between two organic films or in an organic matrix 109. This organic matrix 109 or these organic films comprise at least one compound chosen from the group comprising silicones, fluorinated polymers, polycarbonates, ethylene vinyl acetate (EVA), polyethylene (PE), polymethyl methacrylate (PMMA), polyvinyl butyral (PVB), glasses, such as phosphate, silicate or borosilicate glasses, and derivatives thereof. According to one embodiment of the present invention, the organic matrix 109 has a mean thickness of between 2.5 and 4 mm. In one embodiment of the invention, the organic films have a mean thickness of between 200 and 600 μm.

Each photovoltaic cell 107 has for example a constant nominal voltage of 0.5 V. The power of the photovoltaic cells 107 depends on the intensity of the current generated, which depends on the surface area of each photovoltaic cell 107. A photovoltaic module 101 according to one embodiment of the invention thus makes it possible to generate a voltage of around 19 V in order to be able to serve a battery with an electrochemical charge of 12-15 V. A photovoltaic module 101 may comprise typically 40 photovoltaic cells 107. According to one embodiment of the present invention, the photovoltaic cells 107 of the photovoltaic module 101 are connected, by electrical connectors 111, for example made from tin-plated copper, to each other in series and to a connection box 113 associated with the photovoltaic module 101.

In an application of the photovoltaic module 101 to the covering of agricultural greenhouses, the quantity of light energy entering an agricultural greenhouse for the growth of plant species and the quantity of photovoltaic current delivered by all the photovoltaic cells 107 are determined by the “cell packing factor” of a photovoltaic module 101. The cell packing factor of the photovoltaic module 101 is defined by the ratio of the surface area of all the photovoltaic cells 107 to the total surface area of the collection of photons of the photovoltaic module 101. The applicant has shown that a cell packing factor of less than 1, advantageously between 0.2 and 0.8, makes it possible to provide the photovoltaic function of the photovoltaic cells 107 while enhancing the illumination of the plant species. According to another embodiment of the invention, the cell packing factor is between 0.4 and 0.6.

The applicant has in particular advantageously shown that the photovoltaic modules 101 according to one embodiment of the invention, in which the cell packing factor of the photovoltaic modules is 0.5 and in which the photovoltaic modules comprise a layer of light-cascade doped material enhancing photosynthesis, afford an increase in efficiency of around 50% in diffuse illumination and that moreover the plant species cultivated in agricultural greenhouses covered with the photovoltaic module 101 experience production yields that may range from 1.25 to 1.50 compared with those of cultivations under conventional shelters. The photovoltaic cells 107 used in a photovoltaic module 101 according to one embodiment of the present invention are square or circular in shape, of the “wafer” type. In a preferred embodiment of the present invention, the use of photovoltaic cells 107 of the “wafer” shape gives a natural cell packing factor, provides better sunshine on the plant species and avoids a loss of material during the fabrication of the photovoltaic cells 107.

In a preferred embodiment of the present invention, for standardised solar radiation of AM 1.5, the surface of an agricultural greenhouse covered by a photovoltaic module 101 is advantageously 50% shared by the surface of photovoltaic cells 107 and 50% by the surface of the rear or interior substrate 105 that is not covered by the photovoltaic cells 107. This configuration enables the photovoltaic module to have a cell packing factor of 0.5. However, in a period of light deficit or diffuse light, in a northern region for example, priority must be given to the photon collection surface. It is then possible to reduce the cell packing factor of the photovoltaic module 101 and to favour entries of light into the agricultural greenhouse.

This is because, in the field of plant physiology, apart from the need for a fertile earth, constant maintenance from the nutritional point of view, pesticide treatment, pH balance and density, light is another parameter of importance also to be taken into account. A minimum quantity of light is necessary for the photosynthesis process to be able to operate. However, an excess of light is to be avoided in order to spare the plant species unnecessary heating causing saturation of the chlorophyll function.

Moreover, the spectral quality of the light received by the plant species is also a very important parameter. This is because the majority of plant species with green leaves do not absorb, or absorb only a little, the wavelength lying in the ultraviolet radiation range (wavelengths of between 300 and 400 nm) and green radiation range (wavelengths of between 510 and 590 nm).

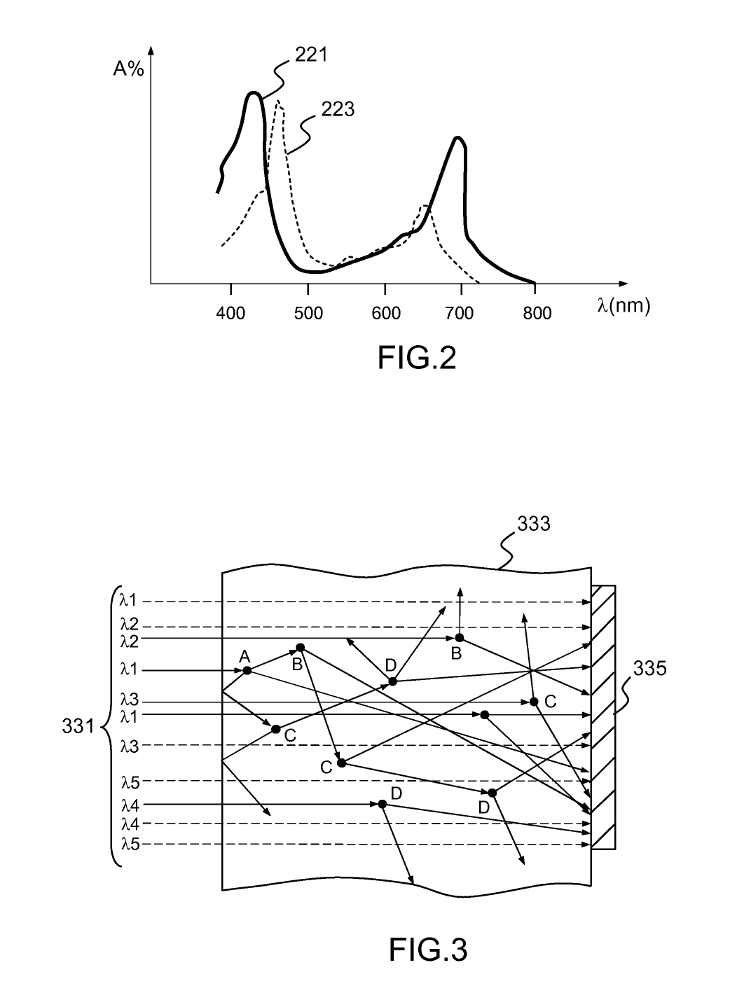

The other wavelengths correspond to the spectral range of absorption of a chromoprotein, commonly referred to as phytochrome. This phytochrome exists in two forms of isomer, chlorophyll A and chlorophyll B. FIG. 2 is a graph (relative energy A %=f(wavelength A)) representing the absorption spectra of the two types of chlorophyll present in plant species. FIG. 2 shows that chlorophyll A, curve 221, and chlorophyll B, curve 223, absorb sunlight in the blue radiation range (wavelengths between 410 and 500 nm) and red radiation range (wavelengths between 600 and 750 nm).

It is at the level of this phytochrome that the photosynthesis process takes place. The photons are converted into an agent (enzyme) reducing carbon dioxide and oxidising water. This simultaneous reduction and oxidation give rise to a glucid member satisfying the energy requirements and the requirement for growth of the plant species.

Another light parameter of importance for the growth of plant species is photoperiodism. Photoperiodism is determined by the photophase, the period of sensitivity to light of the plant species, succeeded by a scotophase, a period of insensitivity to light of plant species. The plant species can be classified in three major categories vis-à-vis photoperiodism: the so-called long-day photoperiodic species, the so-called short-day nyctiperiodic species and the species indifferent to photoperiodism.

The applicant showed that, by combining a photovoltaic module with a cell packing factor of less than 1 and the use of a specific material for optimising the spectral quality of the light received by the plant species, it was possible to increase the efficiency of the greenhouses while keeping the photovoltaic function. The modification of the solar spectrum by the photovoltaic module 101 according to one embodiment of the present invention is made by virtue of the presence of a band-shift material, otherwise referred to as the “light cascade” type, able to absorb sunlight in at least one range of wavelengths in order to re-emit it at least a second wavelength range favourable to the photosynthesis of plant species. In the remainder of the description, this type of description will be referred to as “light-cascade doped material enhancing photosynthesis”.

In one embodiment of the present invention, the light-cascade doped material enhancing photosynthesis absorbs sunlight in the range of wavelengths 300 to 400 nm in order re-emit in the wavelength range 410 to 500 nm. The light-cascade doped material enhancing photosynthesis may also, simultaneously with or as an alternative to the previous embodiment of the invention, absorb sunlight in the wavelength range 510 to 590 nm in order to re-emit it in the wavelength range 600 to 750 nm. The purpose of a light-cascade is to mobilise, at an element of interest, the maximum energy in the range with the greater spectral sensitivity of this element for a maximum efficiency of this element.

In principle, the solar energy used is defined by the area of overlap of the emission spectra of sunlight and the spectral range of interest for the element in question. Therefore, because of the specificity of the element in question and the fact that the energy recovered by the element depends on the intensity of the light being received by the element, that is to say the number of photons transported, one of means of increasing the efficiency of the element in question is to make usable the photons of the part of the solar spectrum situated outside the range of greatest sensitivity of said element in question. The method used, referred to as “light cascade”, transforms the photons having a wavelength situated outside the range of greatest sensitivity of the element considered using the luminescent and/or fluorescent properties of certain chemical compounds, of the optically active material OAM or optically active crystal OAC type, taken as intermediates in the transportation of the energy issuing from the sunlight. The compounds are chosen so that their absorption spectra constitute successive absorption/emission zones making it possible to cover the whole of the solar spectrum in the visible zone (frequency or wavelength overlap).

FIG. 3 shows the operating principle of a light cascade. Solar radiation 301 of given wavelength λ₁, λ₂, λ₃, λ₄, λ₅ can be absorbed by the chemical compound the absorption spectrum of which comprises this value λ₁, λ₂, λ₃, λ₄, λ₅. The photons that excited the molecules of this compound (absorption phenomena) are thus extracted definitively from the incident light beam 301. The return to the fundamental state (the stable state of the molecules at a given temperature) can be effected partly and advantageously by a radiative emission (fluorescence and/or phosphorescence). The photons thus generated correspond to the absorption spectrum of another chemical compound that takes over.

A given compound can absorb either the emission of the compound that precedes it in the sequence of compounds used, or the part of the emission of the solar spectrum that corresponds to it. As illustrated by FIG. 3, the doped matrix 333, intermediate between the incident solar radiation 331 of wavelength λ₁, λ₂, λ₃, λ₄, λ₅ and an element of interest 335, comprises active centres A, B, C, D corresponding to the various OAM or OAC compounds constituting the doped matrix 333. By way of example, the active centres A convert the photons of wavelength λ₁ corresponding to the ultraviolet into photons of wavelength λ₂ corresponding to blue, the active centres B converting the photons of wavelength λ₂ corresponding to blue into photons of wavelength λ₃ corresponding to green, the active centre C converting the photons of wavelength λ₃ corresponding to green into photons of wavelength λ₄ corresponding to yellow, and the active centres D convert the photons of wavelength λ₄ corresponding to yellow into photons of wavelength λ₅ corresponding to red. The solar rays entering the doped matrix 333 comprise photons that either strike the element of interest 335 without having undergone transformation (represented by the discontinuous arrows in FIG. 3) or strike the active centres A, B, C, D and/or the element of interest 335 that has undergone one or more transformations (represented by the continuous arrows in FIG. 3).

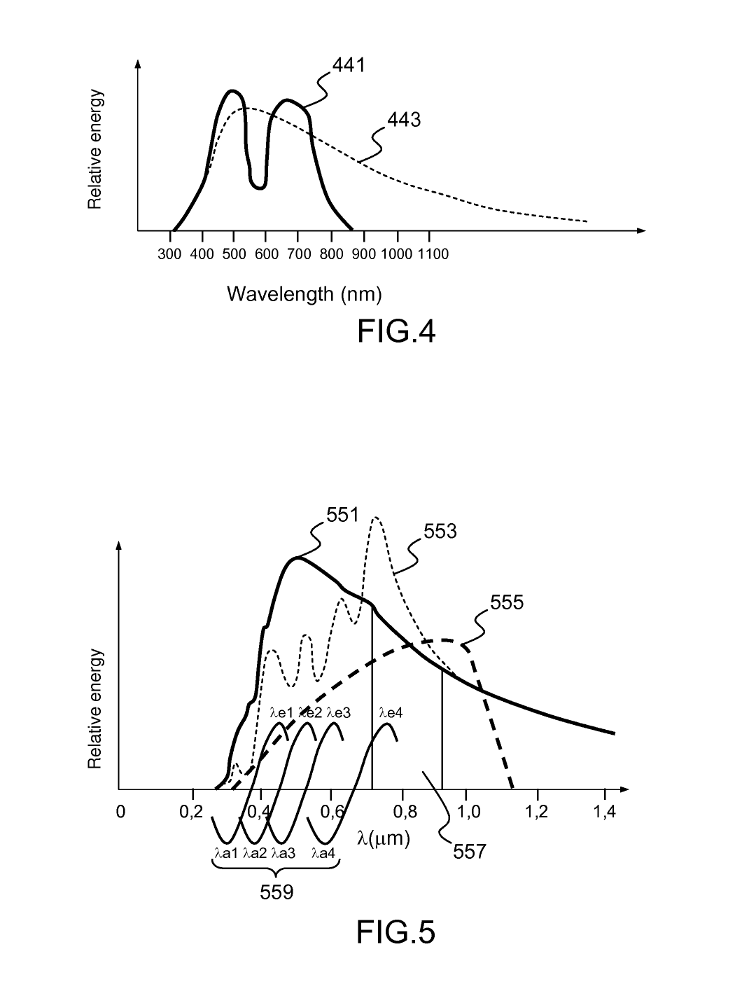

This “light cascade” principle is applied to enhance the photosynthesis of plant species. FIG. 4 is a graph (relative energy=f(wavelength)) representing the solar spectrum 443 and the solar spectrum 441 modified by a photovoltaic module 101 comprising a light-cascade doped material enhancing photosynthesis according to one embodiment of the present invention. The photovoltaic module 101 according to one embodiment of the present invention concentrates all the wavelength bands of the solar radiation that are favourable to the growth and development of plant species. This is illustrated by FIG. 4, where it can be seen that the solar spectrum 441 as modified by a photovoltaic module 101 according to one embodiment of the invention absorbs the sunlight in the wavelength range 300 to 400 nm in order to re-emit it in the wavelength range 410 to 500 nm, and also absorbs the sunlight in the wavelength range 510 to 590 nm in order to re-emit it in the wavelength range 600 to 750 nm.

To modify the solar spectrum, two optically active compounds or more are dispersed in the light-cascade doped material enhancing photosynthesis in order to form a light cascade with two or more levels. These optically active compounds have an absorbent capacity in the wavelengths not favourable to the photosynthesis of plant species, i.e. 300 to 400 nm and 510 to 590 nm for example, and have absorption and emission spectra overlapping according to the previously explained principle, so as to obtain the required transfer of energy. These optically active compounds must also be compatible with the light-cascade doped material enhancing photosynthesis in which they are dispersed.

According to one embodiment of the invention, the light-cascade doped material enhancing photosynthesis is included or coated on at least one of the front plate 103 and the rear substrate 105. Alternatively, the light-cascade doped material enhancing photosynthesis can be included in the organic matrix 109 or in at least one of the two organic films between which photovoltaic cells 107 are arranged.

According to another embodiment of the invention, the light-cascade doped material enhancing photosynthesis is coated on at least the front plate 103 and the rear substrate 105. The light-cascade doped material enhancing photosynthesis then comprises a matrix, in one embodiment of the invention, comprising at least one compound chosen from the group comprising silicones, fluorinated polymers, polycarbonates, ethylene vinyl acetate (EVA), polyethylene (PE), polymethyl methacrylate (PMMA), polyvinyl butyral (PVB), glasses, such as phosphate, silicate or borosilicate glasses, and derivatives thereof.

In one embodiment of the invention, the optically active compounds included in the light-cascade doped material enhancing photosynthesis are chosen from the group comprising lanthanides, the uranyl ion, the aromatic cyclic compounds of the N-ring type, N being an integer chosen from 3, 4, 5 or more, and derivatives thereof. According to a particular embodiment of the invention, the lanthanides are chosen from the group comprising praseodymium, neodymium, samarium, europium and derivatives thereof. According to a particular embodiment of the invention, the aromatic cyclic compounds of the N-ring type are chosen from the group comprising diphenyloxazole, uranin S, rhodamine B, anthracene, pentacene, uvitex MD, naphthacene, hexacene, yellow 8G, red GG and derivatives thereof.

The concentration of the various optically active compounds present in the light-cascade doped material enhancing photosynthesis depends essentially on the thickness of the layer of light-cascade doped material enhancing photosynthesis. Said concentration complies with the Beer-Lambert law. Solely by way of example, for a plate containing the light-cascade doped material enhancing photosynthesis having a thickness 3 mm, the concentrations of the optically active compounds can be between 10⁻³ and 10⁻⁶% by weight. The applicant has advantageously shown that a modification at the level of the concentration of said optically active compounds give rise to a shift and/or a broadening of the emission spectrum of said compounds, and hence the possibility of having an influence on the modification of the solar spectrum by acting on the concentrations.

The applicant showed that it was also possible, according to a variant embodiment, to assist the photovoltaic function of the photovoltaic module 101. For this purpose, according to one embodiment of the present invention, the rear substrate 105 of the photovoltaic module 101 comprises or is coated with a light-cascade doped material enhancing photosynthesis and the front plate 103 of the photovoltaic module 101 comprises or is coated with a “light-cascade doped material enhancing the photovoltaic function”, which is a band-shift material (light cascade), capable of absorbing sunlight in at least one range of wavelengths in order to re-emit it in at least a second range of wavelengths with greater sensitivity of the photovoltaic cells 107. Alternatively, the light-cascade doped material enhancing the photovoltaic function can be included in the organic matrix 109 or in at least one of the two organic films between which the photovoltaic cells 107 are placed.

The photovoltaic module 101 according to one embodiment of the present invention thus makes it possible to shift the solar spectrum towards the wavelength ranges with greater sensitivity of the photovoltaic cells 107. This is illustrated by FIG. 5. The curve 551 illustrates this solar spectrum, the curve 553 illustrates the solar energy spectrum transformed by a photovoltaic module 101 according to one embodiment of the invention and the curve 555 illustrates the spectral response of a photovoltaic cell made from mono- or polycrystalline silicon. The area 557 illustrates the range with greatest sensitivity of an example of a photovoltaic cell made from mono- or polycrystalline silicon. The absorption and emission curve 559 of four optically active compounds with absorption peaks respectively λₐ₁, λₐ₂, λₐ₃, λₐ₄, and emission peaks λₑ₁, λₑ₂, λₑ₃, λₑ₄ illustrate an example of a light cascade of a light-cascade doped material enhancing the photovoltaic function.

To modify the solar spectrum, two optically active compounds or more are dispersed in the light-cascade doped material enhancing the photovoltaic function in order to form a light cascade with two levels or more. These optically active compounds have an absorbent capacity in the wavelengths outside the range of greater sensitivity of the photovoltaic cells 101, and have absorption and emission spectra overlapping according to the principle previously explained, so as to obtain the required energy transfer. These optically active compounds must also be compatible with the light-cascade doped material enhancing the photovoltaic function in which they are dispersed.

In one embodiment of the present invention, the photovoltaic cells 107 used are of the monocrystalline or multicrystalline silicon type. In this case, the optically active compounds must absorb the wavelengths 300 to 640 nm and re-emit in the 650 to 750 nm range. According to one embodiment of the present invention, the photovoltaic cells 107 used are of the amorphous silicon type. In this case, the optically active compounds must absorb the wavelengths 300 to 540 nm and re-emit in the range 550 to 650 nm.

When the light-cascade doped material enhancing the photovoltaic function is coated on at least one of the front plate 103 and the rear substrate 105, it comprises a matrix comprising at least one compound chosen from the group comprising silicones, fluorinated polymers, polycarbonates, ethylene vinyl acetate (EVA), polyethylene (PE), polymethyl methacrylate (PMMA), polyvinyl butyral (PVB), glasses, such as phosphate, silicate or borosilicate glasses, and derivatives thereof. In one embodiment of the invention, the optically active compounds included in the light-cascade doped material enhancing photosynthesis are chosen from the group comprising lanthanides, the uranyl ion, the aromatic cyclic compounds of the N-ring type, N being an integer chosen from 3, 4, 5 or more, and derivatives thereof. According to a particular embodiment of the invention, the lanthanides are chosen from the group comprising praseodymium, neodymium, samarium, europium and derivatives thereof. According to a particular embodiment of the invention, the aromatic cyclic compounds of the N-ring type are chosen from the group comprising diphenyloxazole, uranin S, rhodamine B, anthracene, pentacene, uvitex MD, naphthacene, hexacene, yellow 8G, red GG and derivatives thereof.

The concentration of the various optically active compounds present in the light-cascade doped material enhancing photosynthesis depends essentially on the thickness of the layer of light-cascade doped material enhancing photosynthesis. Said concentration complies with the Beer-Lambert law. Solely by way of example, for a plate containing the light-cascade doped material enhancing photosynthesis having a thickness 3 mm, the concentrations of the optically active compounds can be between 10⁻³ and 10⁶% by weight. A modification at the level of the concentration of said optically active compounds give rise to a shift and/or a broadening of the emission spectrum of said compounds, and hence the possibility of having an influence on the modification of the solar spectrum by acting on the concentrations. According to a variant embodiment of the present invention, the photovoltaic module 101 comprises a material both light-cascade doped enhancing photosynthesis and light-cascade doped enhancing the photovoltaic function.

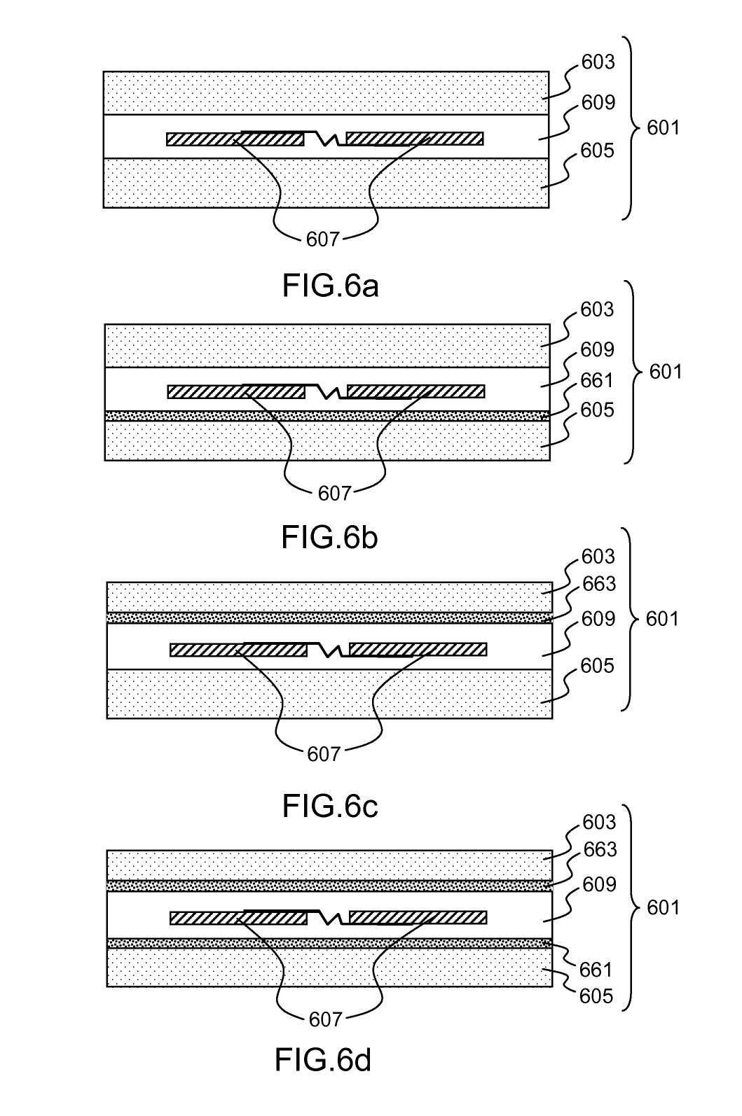

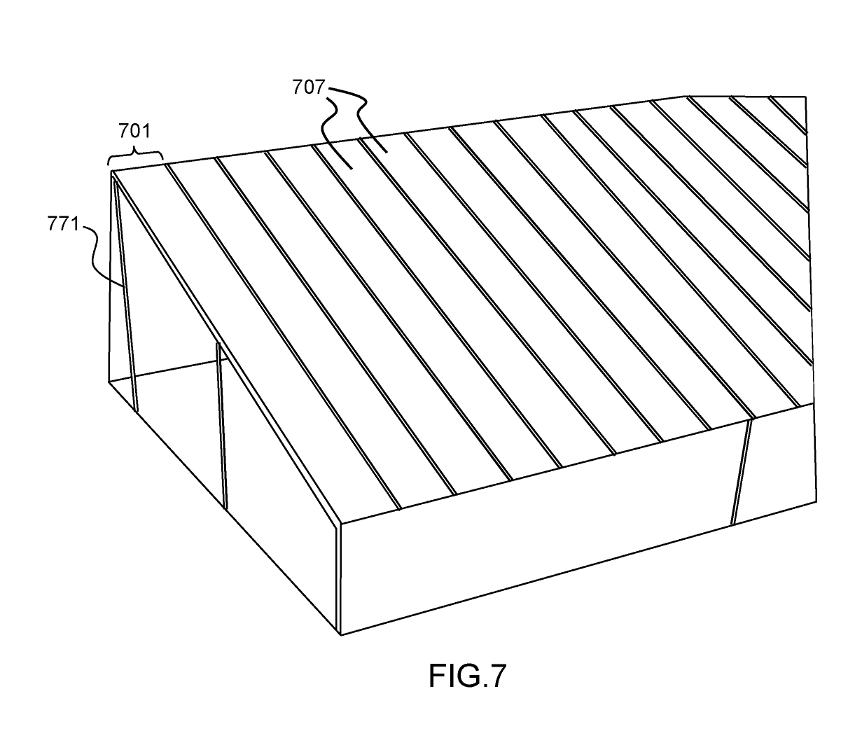

A photovoltaic module according to embodiments of the present invention will now be described with reference to FIGS. 6a to 6d. These embodiments of the photovoltaic module are given only by way of example and do not constitute a limitation to the subject matter of the present invention. FIGS. 6a to 6d are transverse sections of photovoltaic modules according to embodiments of the present invention.

According to one embodiment of the present invention illustrated by FIG. 6a, a photovoltaic module 601 comprises a rear substrate 605, a front plate 603, and a set of photovoltaic cells 607 placed in an organic matrix 609 arranged between the front plate 603 and the rear substrate 605. In a first variant of this embodiment, the front plate 605 comprises a light-cascade doped material enhancing photosynthesis, the organic matrix 609 and the rear substrate 605 comprising a neutral transparent material. In a second variant of this embodiment, the rear substrate 605 comprises a light-cascade doped material enhancing photosynthesis, the organic matrix 609 and the front plate 603 comprising a neutral transparent material. Concomitantly with this second variant, the front plate 603 and/or the organic matrix 609 can comprise a light-cascade doped material enhancing the photovoltaic function.

In a third variant of this embodiment, the organic matrix 609 comprises a light-cascade doped material enhancing photosynthesis, the front plate 603 and the rear substrate comprising a neutral transparent material. Concomitantly with this third variant, the front plate 603 can comprise a light-cascade doped material enhancing the photovoltaic function. In all the variants of this embodiment of the invention, the organic matrix 609 can be replaced by two organic films between which the photovoltaic cells are placed.

According to one embodiment of the present invention illustrated by FIG. 6b, a photovoltaic module 601 comprises a rear substrate 605 comprising a neutral transparent material and coated with a film 661 of light-cascade doped material enhancing photosynthesis, a front plate 603 comprising a neutral transparent material and a set of photovoltaic cells 607 arranged in an organic matrix 609 comprising a neutral transparent material and placed between the front plate 603 and the rear substrate 605. According to a first variant of this embodiment of the present invention, at least one of the organic matrix 609 and the front plate 603 comprises a light-cascade doped material enhancing the photovoltaic function.

In a second variant of this embodiment of the invention, the organic matrix can be replaced by two organic films between which the photovoltaic cells 607 are placed. In this case, the bottom organic film is substituted for the film 661 of light-cascade doped material enhancing photosynthesis. The top organic film can in an additional variant of this embodiment of the invention comprise a light-cascade doped material enhancing the photovoltaic function.

According to one embodiment of the present invention illustrated by FIG. 6c, a photovoltaic module 601 comprises a front plate 603 comprising a neutral transparent material and coated with a film 663 of light-cascade doped material enhancing photosynthesis and/or light-cascade doped material enhancing the photovoltaic function, a rear substrate 605 comprising a neutral transparent material, and a set of photovoltaic cells 607 arranged in an organic matrix 609 comprising a neutral transparent material and placed between the front plate 603 and the rear substrate 605. According to a first variant of this embodiment of the present invention, at least one of the organic matrix 609 and the rear substrate 605 comprises a light-cascade doped material enhancing photosynthesis.

In a second variant of this embodiment of the invention, the organic matrix can be replaced by two organic films between which the photovoltaic cells 607 are placed. In this case, the top organic film is substituted for the film 663 comprising the light-cascade doped material. The bottom organic film can, in an additional variant of this embodiment of the invention, comprise a light-cascade doped material enhancing photosynthesis.

According to one embodiment of the present invention illustrated by FIG. 6d, a photovoltaic module 601 comprises a rear substrate 605 comprising a neutral transparent material and coated with film 661 of light-cascade doped material enhancing photosynthesis, a front plate 603 comprising a neutral transparent material and coated with a film 663 of light-cascade doped material enhancing the photovoltaic function, and a set of photovoltaic cells 607 arranged in an organic matrix 609 comprising a neutral transparent material and placed between the front plate 603 and the rear substrate 605. In a particular embodiment of the present invention, a photosynthesis module 601 comprises a front plate 603 and a rear substrate 605 comprising extra-white glass, as well as a set of photovoltaic cells 607 arranged in a matrix comprising transparent ethylene vinyl acetate. The rear substrate 605 is coated with a film comprising light-cascade doped polyethylene enhancing photosynthesis.

In another particular embodiment of the present invention, a photovoltaic module 601 comprises a front plate 603 comprising transparent polymethyl methacrylate and a rear substrate 605 comprising light-cascade doped polymethyl methacrylate enhancing photosynthesis, as well as a set of photovoltaic cells 607 arranged in a transparent polymethyl methacrylate matrix. In another particular embodiment of the present invention, a photovoltaic module 601 comprises a front plate 603 comprising light-cascade doped polymethyl methacrylate enhancing the photovoltaic function and a rear substrate 605 comprising light-cascade doped polymethyl methacrylate enhancing photosynthesis, as well as a set of photovoltaic cells 607 arranged between two organic films comprising a neutral transparent material. According to another embodiment of the invention, a photovoltaic module comprises a front plate 603 comprising transparent glass, a rear substrate 605 comprising a transparent fluorinated polymer, and a set of photovoltaic cells 607 arranged between two organic films comprising ethylene vinyl acetate, the top film comprising a light-cascade doped material enhancing the photovoltaic function and the bottom film comprising a light-cascade doped material enhancing photosynthesis.

According to one embodiment of the present invention, an agricultural greenhouse is covered on at least part of its surface with at least one photovoltaic module. FIG. 7 shows an example of an agricultural greenhouse 771 covered with photovoltaic modules 701 comprising a set of photovoltaic cells 707 according to one embodiment of the present invention.

The present invention also concerns a method of manufacturing photovoltaic modules of the type comprising a front plate intended to be in contact with sunlight, a rear substrate and a set of photovoltaic cells (107, 707) arranged between the front plate (103) and the rear substrate (105). The method comprises at least the steps of distribution of the photovoltaic cells on the rear substrate so that the photovoltaic module obtained has a cell packing factor of between 0.2 and 0.8, and incorporation in or coating on at least one of the front plate and the rear substrate of a light-cascade doped material enhancing photosynthesis able to absorb sunlight in at least one range of wavelengths in order to re-emit it in at least a second range of wavelengths favourable to photosynthesis of at least one plant species.

The invention thus described has in particular the following advantages. The photovoltaic modules according to the embodiments of the present invention may bivalent or multifunction. They enhance the growth of plant species placed in an agricultural greenhouse equipped with such modules and, concomitantly, they enhance the production of photoelectric current.

The invention, although having been described in a particular example embodiment illustrated by the various figures, extends to all variants and modifications appearing obviously to a person skilled in the art, within the limit of the technical features defined in the claims.

1. A photovoltaic module for an agricultural greenhouse, comprising:
a front plate adapted to be in contact with sunlight;
a rear substrate; and
a set of photovoltaic cells arranged between the front plate and the rear substrate;
a cell packing factor of the photovoltaic module is between approximately 0.2 and 0.8; and
at least one layer of a light-cascade doped material enhancing photosynthesis able to absorb sunlight in at least one range of wavelengths in order to re-emit it in at least a second range of wavelengths favourable to the photosynthesis of at least one plant species.

2. A photovoltaic module according to claim 1, wherein at least one of the front plate and the rear substrate forms or is coated with a layer of the light-cascade doped material enhancing photosynthesis.

3. A photovoltaic module according to claim 1, wherein all of the photovoltaic cells are arranged in an organic matrix or between two organic films.

4. A photovoltaic module according to claim 3, wherein at least one of the organic matrix and the two organic films forms the layer of the light-cascade doped material enhancing photosynthesis.

5. A photovoltaic module according to claim 1, wherein the light-cascade doped material enhancing photosynthesis absorbs sunlight in the range of wavelengths 300 to 400 nm in order to re-emit in the wavelength range 410 to 500 nm.

6. A photovoltaic module according to claim 1, wherein the light-cascade doped material enhancing photosynthesis absorbs sunlight in the range of wavelengths 510 to 590 nm in order to re-emit in the wavelength range 600 to 750 nm.

7. A photovoltaic module according to claim 1, wherein
the front plate and the rear substrate of the photovoltaic module comprise glass; and
at least one of the front plate and rear substrate is coated with the light-cascade doped material enhancing photosynthesis.

8. A photovoltaic module according to claim 1, wherein
the front plate and the rear substrate of the photovoltaic module comprise polymethyl methacrylate; and
at least one of the front plate and rear substrate forms the light-cascade doped material enhancing photosynthesis.

9. A photovoltaic module according to claim 1, wherein
the rear substrate forms or is coated with the light-cascade doped material enhancing photosynthesis; and
the front plate of the photovoltaic module forms or is coated with a layer of a light-cascade doped material enhancing the photovoltaic function able to absorb sunlight in at least one range of wavelengths in order to re-emit it in at least a second range of wavelengths with greater sensitivity of the photovoltaic cells.

10. A photovoltaic module according to claim 1, wherein the layer of the light-cascade doped material enhancing the photovoltaic function or enhancing photosynthesis comprises a matrix comprising at least one compound chosen from the group comprising silicones, polycarbonates, ethylene vinyl acetate, polyethylene, polymethyl methacrylate, polyvinyl butyral, glasses and derivatives thereof.

11. A photovoltaic module according to claim 1, wherein the light-cascade doped material enhancing the photovoltaic function or enhancing photosynthesis comprises at least one compound chosen from the group comprising lanthanides, the uranyl ion, the aromatic cyclic compounds of the type with N rings, N being an integer chosen from 3, 4, 5 or more, and derivatives thereof.

12. An agricultural greenhouse covered on at least part of its surface with at least one agricultural greenhouse photovoltaic module the agricultural greenhouse photovoltaic module comprising:
a front plate receiving sunlight;
a rear substrate;
photovoltaic cells located between the front plate and the rear substrate;
a cell packing factor of the agricultural greenhouse photovoltaic module being between substantially 0.2 and 0.8; and
a light-cascade doped material absorbing the sunlight in at least one range of wavelengths and re-emitting it in at least a second range of wavelengths favourable to enhance photosynthesis of at least one plant species, in the greenhouse.

13. A method of manufacturing photovoltaic modules, the method comprising:
locating a front plate to be in contact with sunlight;
arranging a set of photovoltaic cells arranged between the front plate and a rear substrate;
distributing the photovoltaic cells on the rear substrate so that the photovoltaic module obtained has a cell packing factor of between approximately 0.2 and 0.8; and
at least one of: incorporating in or cladding, on at least one of the front plate and the rear substrate of a light-cascade doped material enhancing photosynthesis able to absorb sunlight in at least one range of wavelengths in order to re-emit it in at least a second range of wavelengths favourable to photosynthesis of at least one plant species.
